(19) United States
(12) Patent Application Publication
(10) Pub. No.: US 2021/0013214 A1
(43) Pub. Date: Jan. 14, 2021

(54) APPARATUS INCLUDING ACCESS LINE STRUCTURES AND RELATED METHODS AND ELECTRONIC SYSTEMS

(71) Applicant: Micron Technology, Inc., Boise, ID (US)

(72) Inventor: Shinobu Terada, Higashihiroshima (JP)

(21) Appl. No.: 16/506,704

(22) Filed: Jul. 9, 2019

(51) Int. Cl. H01L 27/108; G11C 5/06

(52) U.S. Cl. CPC H01L 27/10891; H01L 27/10805; G11C 5/063

(57) ABSTRACT

An apparatus comprising a memory array comprising wordlines, bit lines, and memory cells. Each memory cell is coupled to an associated one of the wordlines and an associated one of the bit lines. Each of the wordlines is buried in a substrate and comprises a lower conductive material, an upper conductive material, and an oxidation material of the lower conductive material between the lower conductive material and the upper conductive material. In additional embodiments, the apparatus comprises access lines, digit lines, and memory cells. The access lines comprise an oxidized material between a first conductive material and a second conductive material, the oxidized material comprising an oxide of the first conductive material. Methods of forming the apparatus and electronic systems are also disclosed.

### TECHNICAL FIELD

Embodiments disclosed herein relate to electronic devices and electronic device fabrication. More particularly, embodiments of the disclosure relate to apparatus including access line structures, and to related electronic systems and methods of forming the apparatus.

### BACKGROUND

A memory device, such as a dynamic random access memory (DRAM) device, includes numerous memory cells, with each memory cell storing one bit of information. A memory cell includes a memory storage element (e.g., a capacitor) and an access device (e.g., a transistor) operably coupled to the memory storage element. A source region or a drain region of the transistor is electrically connected to one of the capacitor terminals. The other of the source region or the drain region and a gate electrode of the transistor are connected to a digit line (e.g., a bit line) and an access line (e.g., a wordline), respectively. In addition, the other capacitor terminal is connected to a reference voltage. The transistor includes a channel region between the source region and the drain region and further includes a gate configured to electrically connect the source region and drain region to one another through the channel region. The channel region includes a semiconductor material, such as silicon. The memory cells are arranged in a matrix of rows and columns.

As DRAM technology advances, memory cells have been scaled down to increase the density of the memory cells. The increase in density increases the storage capacity of the DRAM device. However, the increased density also leads to a decrease in spacing between adjacent wordlines, which increases the coupling effect between the adjacent wordlines. For example, when a row (e.g., a wordline) in the matrix is repeatedly activated and refreshed, noise may be injected into the adjacent row (e.g., a victim row), such that data corruption may occur in one or more memory cells in the victim row. The repeated activation and refreshing of the row are referred to as the row hammer effect. A so-called “row hammer event” occurs when a refresh command is executed to refresh wordlines that are adjacent to a hammered wordline. A particular wordline is “hammered” when it is accessed via memory access operations, such as an active command, in a manner that potentially leads to data errors in adjacent wordlines. Leakage and parasitic currents caused by the hammering of a row may cause data corruption in a non-accessed physically adjacent row (e.g., the victim row).

Some approaches to reduce the adverse effects of row hammering on adjacent rows include refreshing adjacent rows responsive to a determination that the row hammer event has occurred. For example, responsive to determining that a particular row has been the target of repeated accesses (e.g., the row has undergone more than a threshold number of accesses within a refresh period), the physically adjacent neighbor rows may be selected for a targeted refresh operation, which may be referred to as a row hammer refresh operation. However, in conventional DRAM devices, row hammer performance is insufficient.

### BRIEF DESCRIPTION OF THE DRAWINGS

FIG. 1 is a cross-sectional view of an access line structure (e.g., a wordline structure) according to embodiments of the disclosure;

FIGS. 2-6 are cross-sectional views showing various stages of forming the wordline structure of FIG. 1;

FIG. 7 is a cross-sectional view of an electronic device including the wordline structure according to embodiments of the disclosure;

FIG. 8 is a top plan view of an array including the wordline structure according to embodiments of the disclosure, where the view of FIG. 8 is taken along section line A-A of FIG. 7;

FIG. 9 is a schematic block diagram illustrating a system including the wordline structure in accordance with embodiments of the disclosure;

FIGS. 10A and 10B are tunneling electron microscopy (TEM) micrographs of a wordline structure in accordance with embodiments of the disclosure;

FIGS. 11A and 11B are TEM micrographs of a conventional wordline structure;

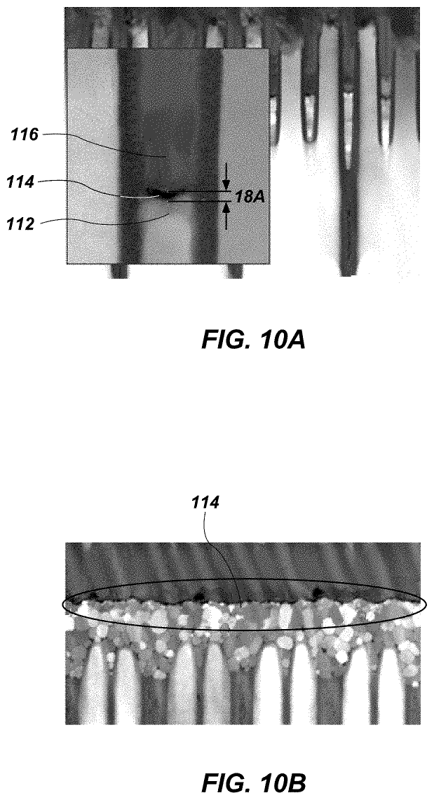

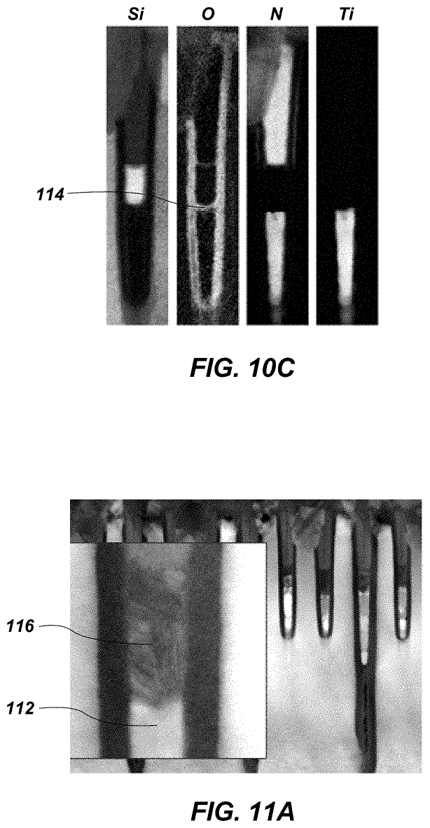

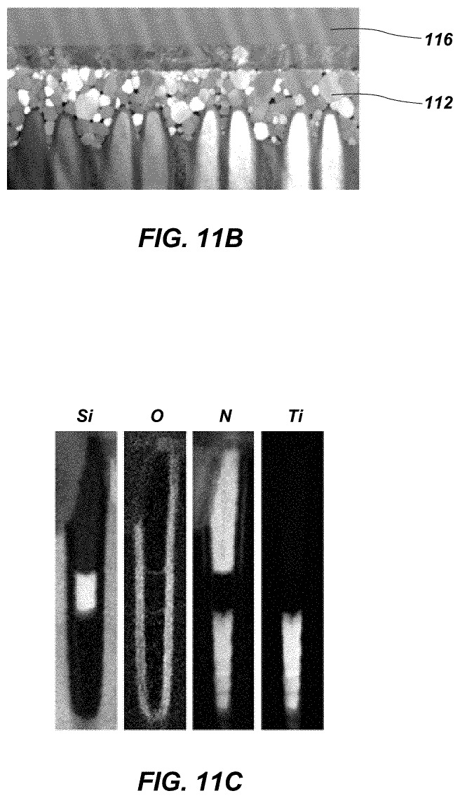

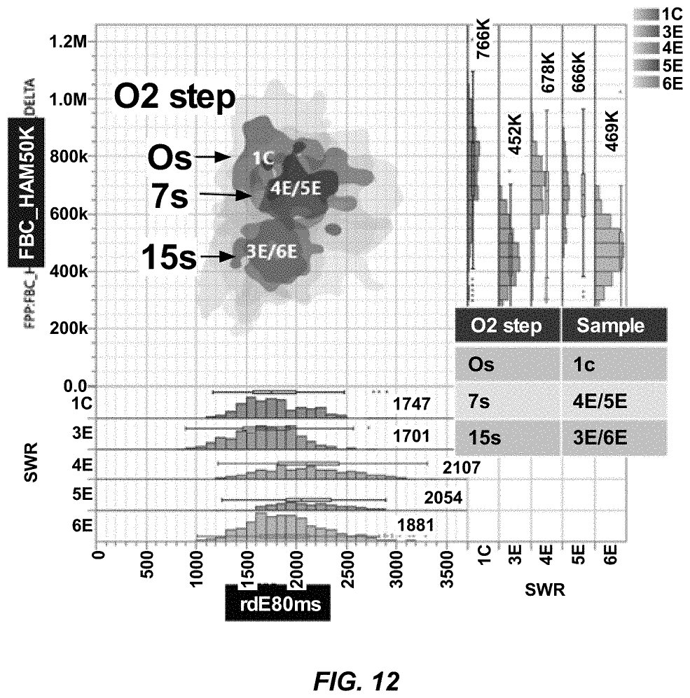

FIGS. 10C and 11C are Electron Energy Loss Spectroscopy (EELS) micrographs of a wordline structure in accordance with embodiments of the disclosure compared to a conventional wordline structure; and

FIG. 12 is a plot of row hammer performance as a function of refresh properties.

### DETAILED DESCRIPTION

An apparatus (e.g., an electronic device, a semiconductor device, a memory device) is disclosed that includes an access line structure (e.g., a wordline structure) having an oxidized material between two conductive materials. The oxidized material is a chemically oxidized material of one of the two conductive materials in the wordline structure. The oxidized material forms an interface between the two conductive materials. The oxidized material is formed by subjecting one of the conductive materials to an oxidation act. The oxidation act is conducted after removing a portion of one of the conductive materials. The conductive materials and the oxidized material constitute a wordline (e.g., a gate) of the apparatus. The apparatus including the wordline structure exhibits improved row hammer performance properties compared to conventional apparatus lacking the oxidized material between the two conductive materials.

The following description provides specific details, such as material types, material thicknesses, and process conditions in order to provide a thorough description of embodiments described herein. However, a person of ordinary skill in the art will understand that the embodiments disclosed herein may be practiced without employing these specific details. Indeed, the embodiments may be practiced in conjunction with conventional fabrication techniques employed in the semiconductor industry. In addition, the description provided herein does not form a complete description of an electronic device or a complete process flow for manufacturing the electronic device and the structures described below do not form a complete electronic device. Only those process acts and structures necessary to understand the embodiments described herein are described in detail below. Additional acts to form a complete electronic device may be performed by conventional techniques.

The materials described herein may be formed by conventional techniques including, but not limited to, spin coating, blanket coating, chemical vapor deposition (CVD), atomic layer deposition (ALD), plasma enhanced ALD, or physical vapor deposition (PVD). Alternatively, the materials may be grown in situ. Depending on the specific material to be formed, the technique for depositing or growing the material may be selected by a person of ordinary skill in the art. The removal of materials may be accomplished by any suitable technique including, but not limited to, etching, abrasive planarization (e.g., chemical-mechanical planarization), or other known methods unless the context indicates otherwise.

Drawings presented herein are for illustrative purposes only, and are not meant to be actual views of any particular material, component, structure, device, or electronic system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

As used herein, the singular forms “a,” “an,” and “the” are intended to include the plural forms as well, unless the context clearly indicates otherwise.

As used herein, “and/or” includes any and all combinations of one or more of the associated listed items.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, the term “apparatus” includes without limitation memory devices, as well as semiconductor devices, which may or may not incorporate memory, such as a logic device, a processor device, or a radiofrequency (RF) device. Further, an apparatus may incorporate memory in addition to other functions such as, for example, a so-called “system on a chip” (SoC) including a processor and memory, or an electronic device including logic and memory. The apparatus may be a 3D electronic device including, but not limited to, a 3D NAND Flash memory device, such as a 3D floating gate NAND Flash memory device or a 3D replacement gate NAND Flash memory device.

As used herein, spatially relative terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, the term “configured” refers to a size, shape, material composition, and arrangement of one or more of at least one structure and at least one apparatus facilitating operation of one or more of the structure and the apparatus in a pre-determined way.

As used herein, reference to an element as being “on” or “over” another element means and includes the element being directly on top of, adjacent to (e.g., laterally adjacent to, vertically adjacent to), underneath, or in direct contact with the other element. It also includes the element being indirectly on top of, adjacent to (e.g., laterally adjacent to, vertically adjacent to), underneath, or near the other element, with other elements present therebetween. In contrast, when an element is referred to as being “directly on” or “directly adjacent to” another element, no intervening elements are present.

As used herein, the terms “oxidized material” or “oxidized conductive material” mean and include a material having oxygen atoms in addition to atoms of the conductive material. The oxidized conductive material may be a stoichiometric material, an oxygen-rich material, or an oxygen-poor material.

As used herein, the term “substantially” in reference to a given parameter, property, or condition means and includes to a degree that one of ordinary skill in the art would understand that the given parameter, property, or condition is met with a degree of variance, such as within acceptable manufacturing tolerances. By way of example, depending on the particular parameter, property, or condition that is substantially met, the parameter, property, or condition may be at least 90.0% met, at least 95.0% met, at least 99.0% met, or even at least 99.9% met.

As used herein, the term “substrate” means and includes a material (e.g., a base material) or construction upon which additional materials are formed. The substrate may be a semiconductor substrate, a base semiconductor layer on a supporting structure, a metal electrode, or a semiconductor substrate having one or more materials, layers, structures, or regions formed thereon. The materials on the semiconductor substrate may include, but are not limited to, semiconductive materials, insulating materials, conductive materials, etc. The substrate may be a conventional silicon substrate or other bulk substrate comprising a layer of semiconductive material. As used herein, the term “bulk substrate” means and includes not only silicon wafers, but also silicon-on-insulator (“SOT”) substrates, such as silicon-on-sapphire (“SOS”) substrates and silicon-on-glass (“SOG”) substrates, epitaxial layers of silicon on a base semiconductor foundation, and other semiconductor or optoelectronic materials, such as silicon-germanium, germanium, gallium arsenide, gallium nitride, and indium phosphide. The substrate may be doped or undoped.

As used herein, the term “wordline structure” means and includes a conductive structure having a first conductive material, an oxidized material, and a second conductive material, with the oxidized material between the first conductive material and the second conductive material.

As used herein, the terms “vertical,” “longitudinal,” “horizontal,” and “lateral” are in reference to a major plane of a structure and are not necessarily defined by Earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure.

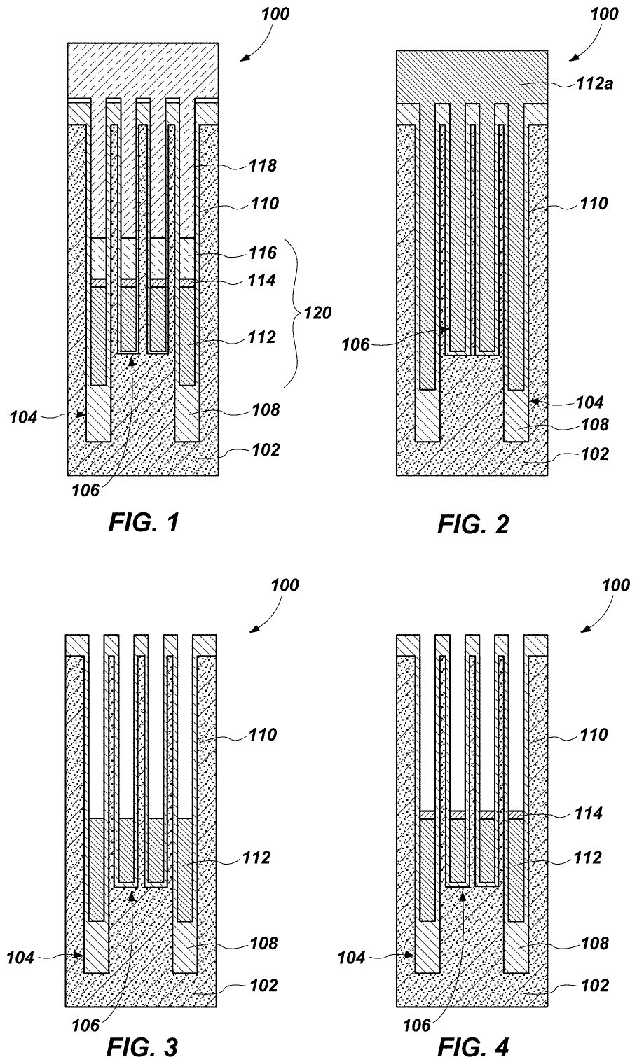

A wordline structure 100 for use in an apparatus (e.g., an electronic device, a memory device (e.g., a DRAM memory device)) is shown in FIG. 1. The apparatus includes the wordline structure 100 and a substrate 102, isolation trenches 104, access line trenches (e.g., wordline trenches 106), a dielectric material 108, a gate dielectric material 110, a first conductive material 112, an oxidized material 114, a second conductive material 116, another dielectric material 118. The wordline structure 100 includes the first conductive material 112, the oxidized material 114, and the second conductive material 116. The first conductive material 112, the oxidized material 114, and the second conductive material 116 form a gate 120 (e.g., a wordline, an access line). The oxidized material 114 is formed on (e.g., directly on) the first conductive material 112, and the second conductive material 116 is formed on (e.g., directly on) the oxidized material 114. A first surface (e.g., a lower surface) of the oxidized material 114 forms an interface with the first conductive material 112, and a second surface (e.g., an upper surface) of the oxidized material 114 forms an interface with the second conductive material 116. The dielectric material 108 and the materials of the gate 120 may be in the isolation trenches 104, and the materials of the gate 120 may be in the wordline trenches 106. The first conductive material 112 (e.g., a lower conductive material) may be configured in the wordline trenches 106 as a layer, although other configurations are possible. The oxidized material 114 may include an oxidized region of the first conductive material 112. The oxidized material 114 may be configured in the wordline trenches 106 as a layer, although other configurations are possible. The second conductive material 116 may be configured in the wordline trenches 106 as a layer, although other configurations are possible.

By way of example only, the first conductive material 112 may be a metal material (e.g., a transition metal) or a metal nitride material (e.g., a transition metal nitride), such as one or more of titanium nitride, tungsten, or ruthenium. In some embodiments, the first conductive material 112 is titanium nitride. In other embodiments, the first conductive material 112 is tungsten. In yet other embodiments, the first conductive material 112 is ruthenium.

The oxidized material 114 may include one or more oxygen atoms in addition to the metal atoms or the metal atoms and nitrogen atoms of the first conductive material 112. If, for example, the first conductive material 112 is titanium nitride, tungsten, or ruthenium, the oxidized material 114 may be a titanium oxynitride (TiN_{y}O_{z}), where y is a real number greater than about 0 and less than about 1.0 and z is a real number greater than about 0 and less than or equal to about 2.0; a tungsten oxide (WOₓ), such as W₂O₃, WO₂, WO₃; or a ruthenium oxide (RuOₓ), such as RuO₂. In some embodiments, the oxidized material 114 is titanium oxynitride. The titanium oxynitride may be a stoichiometric titanium oxynitride, an oxygen-rich titanium nitride, or an oxygen-poor titanium nitride. However, the oxidized material 114 excludes titanium oxide having substantially no nitrogen atoms and titanium nitride having substantially no oxygen atoms. In other embodiments, the oxidized material 114 is tungsten oxide (WOₓ). In yet other embodiments, the oxidized material 114 is ruthenium oxide (RuOₓ). The oxidized material 114 may exhibit a thickness of between about 1 nm and about 3 nm, such as between about 1 nm and about 2 nm, between about 2 nm and about 3 nm, between about 1.5 nm and about 2.5 nm, between about 1.0 nm and about 1.5 nm, between about 1.5 nm and about 2.0 nm, between about 2.0 nm and about 2.5 nm, or between about 2.5 nm and about 3.0 nm.

The second conductive material 116 may be a conductive material having a different work function than the first conductive material 112 or having the same work function as the first conductive material 112. The second conductive material 116 may be a metal material (e.g., a transition metal), a metal nitride material (e.g., a transition metal nitride), or polysilicon. The second conductive material 116 may include, but is not limited to, titanium nitride, tungsten, ruthenium, or polysilicon. In some embodiments, the second conductive material 116 is polysilicon.

In some embodiments, the wordline structure 100 includes titanium nitride as the first conductive material 112, titanium oxynitride as the oxidized material 114, and polysilicon as the second conductive material 116.

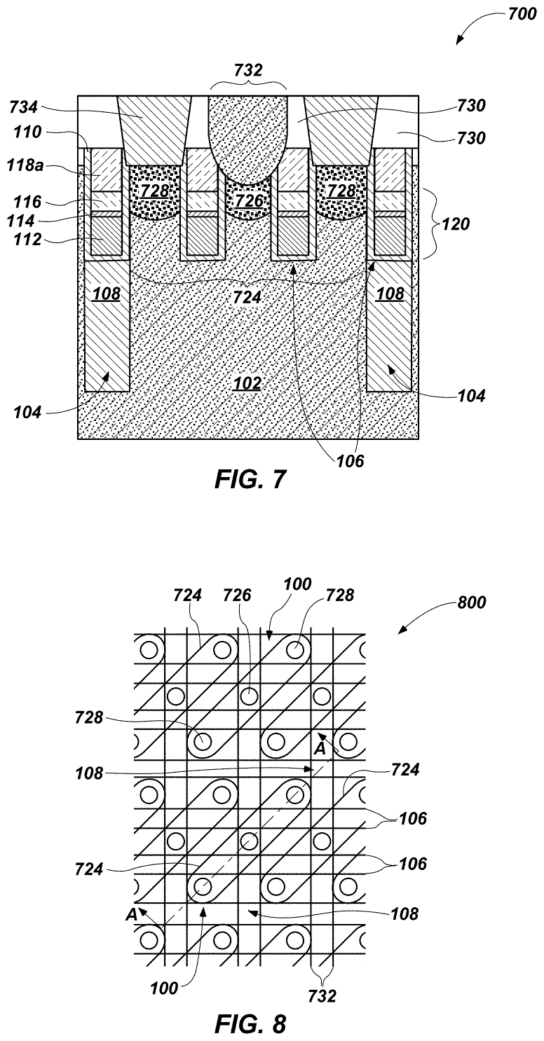

The isolation trenches 104 provide shallow trench isolation (STI) for active areas 724 (see FIG. 7) of the substrate 102. The isolation trenches 104 may be defined by sidewalls of the substrate 102. The isolation trenches 104 may be partially filled with the dielectric material 108, such as at the bottom of the isolation trenches 104. The dielectric material 108 may include, but is not limited to, an oxide (e.g., silicon dioxide (SiO₂)), a nitride (e.g., silicon nitride (SiN)), or an oxynitride. One or more of the isolation trenches 104 may include one of the wordline trenches 106. For example, one access line trench 106 may be formed within one of the isolation trenches 104. The isolation trenches 104 may also contain the first conductive material 112, the oxidized material 114, the second conductive material 116, and the another dielectric material 118. The gate dielectric material 110 may be present in the isolation trenches 104, such as on sidewalls of the substrate 102, while the dielectric material 108 is present in the bottom of the isolation trenches 104. The gate dielectric material 110 may surround the first conductive material 112, the oxidized material 114, and the second conductive material 116 in the isolation trenches 104. The dielectric material 108 and the gate dielectric material 110 may be the same material as one another or a different material from one another. The first conductive material 112 may be over (e.g., directly over, directly adjacent to, vertically adjacent to) the dielectric material 108 in the isolation trenches 104, the oxidized material 114 may be over (e.g., directly over, directly adjacent to) the first conductive material 112, and the second conductive material 116 may be over (e.g., directly over, directly adjacent to, vertically adjacent to) the oxidized material 114. The remainder of the isolation trenches 104 may contain the another dielectric material 118. The another dielectric material 118 may be the same material as the dielectric material 108 or as the gate dielectric material 110, or may be a different material from the dielectric material 108 and/or the gate dielectric material 110.

The wordline trenches 106 (e.g., access line trenches) traverse the active areas 724. In the active areas 724, a pair of the wordline trenches 106 may separate a source 726 (see FIG. 7) from drains 728 (see FIG. 7), with the drains 728 disposed to either side of the source 726. The source 726 and drains 728 may be defined by doped areas of the substrate 102 proximate an upper surface of the substrate 102. For example, the source 726 and the drains 728 may be doped with an n-type dopant or with a p-type dopant. The source 726 and the drains 728 may be formed by conventional techniques. The wordline trenches 106 may be defined by sidewalls of the substrate 102. The wordline trenches 106 contain the first conductive material 112, the oxidized material 114, the second conductive material 116, and the another dielectric material 118, as well as the gate dielectric material 110 on the sidewalls of the substrate 102.

The gate dielectric material 110 may be present in the isolation trenches 104 and in the wordline trenches 106, such as on the sidewalls of the substrate 102. The gate dielectric material 110 may include, but is not limited to, silicon dioxide or silicon nitride. The gate dielectric material 110 may be the same material as or a different material than the dielectric material 108 in the isolation trenches 104. The isolation trenches 104 and the wordline trenches 106 contain the gate 120 (e.g., the first conductive material 112, the oxidized material 114, and the second conductive material 116) and the remainder of the isolation trenches 104 and the wordline trenches 106 contain the another dielectric material 118. The wordline structure 100 including the gate 120 in the wordline trenches 106 may, therefore, be a so-called “buried wordline” in the substrate 102 since the gate 120 is isolated from the source 726 and drains 728 by the gate dielectric material 110.

To form the wordline structure 100, the isolation trenches 104 and the wordline trenches 106 are formed in the substrate 102, such as a silicon substrate. The isolation trenches 104 and the wordline trenches 106 are formed by conventional techniques. The isolation trenches 104 and the wordline trenches 106 may be high aspect ratio openings, such as having an aspect ratio of greater than or equal to about 10:1, greater than or equal to about 20:1, or greater than or equal to about 50:1. A depth of the isolation trenches 104 into the substrate 102 may be greater than a depth of the wordline trenches 106. The isolation trenches 104 may extend deeper into the substrate 102 than the wordline trenches 106. The isolation trenches 104 and the wordline trenches 106 may be formed in the substrate 102 in a single act or in multiple acts.

The dielectric material 108 may be formed in the bottom of the isolation trenches 104, and the gate dielectric material 110 may be formed on the sidewalls of the substrate 102, as shown in FIG. 2. The dielectric material 108 and the gate dielectric material 110 may be the same material or a different material. The gate dielectric material 110 may be formed on the sidewalls of the substrate 102 in the isolation trenches 104 and the wordline trenches 106, such as conformally formed on the sidewalls of the substrate 102.

The first conductive material 112a may be formed in the isolation trenches 104 and in the wordline trenches 106, as shown in FIG. 2. The first conductive material 112a may be formed in the isolation trenches 104 and in the wordline trenches 106 by conventional techniques. The first conductive material 112a (e.g., the lower conductive material) may be one of the materials previously discussed. The first conductive material 112a may substantially fill the isolation trenches 104 and the wordline trenches 106 and form over an upper surface of the substrate 102.

A removal act may be conducted to remove a portion of the first conductive material 112a extending over the upper surface of the substrate 102, as well as a portion of the first conductive material 112a within the isolation trenches 104 and the wordline trenches 106, as shown in FIG. 3. One or more removal acts may be conducted to recess the first conductive material 112a in the isolation trenches 104 and the wordline trenches 106. The first conductive material 112a may be removed by conventional techniques, forming the first conductive material 112 recessed within the isolation trenches 104 and the wordline trenches 106. Following the removal act, the first conductive material 112 may partially fill the isolation trenches 104 and the wordline trenches 106, with a portion of the sidewalls of the gate dielectric material 110 exposed. By way of example only, a dry etch process may be conducted to form the recessed first conductive material 112 in the isolation trenches 104 and in the wordline trenches 106.

An oxidation act may be conducted to oxidize a portion of the first conductive material 112 to form an oxidized material 114 (e.g., an oxidized first conductive material) in the isolation trenches 104 and the wordline trenches 106, as shown in FIG. 4. The oxidized material 114 is adjacent to (e.g., directly over, vertically adjacent to) the first conductive material 112. The first conductive material 112 and the oxidized material 114 may partially fill the isolation trenches 104 and the wordline trenches 106. The oxidized material 114 may, for example, be formed at a thickness of from about 1 nm to about 3 nm. The oxidation act may be conducted after recessing the first conductive material 112a in the isolation trenches 104 and the wordline trenches 106. Depending on the material used as the first conductive material 112, the oxidized first conductive material 112 may be titanium oxynitride, tungsten oxide, or ruthenium oxide.

The oxidation act may be a plasma oxidation act in which the first conductive material 112 in the isolation trenches 104 and the wordline trenches 106 is exposed to an oxygen-containing plasma to incorporate oxygen into the first conductive material 112, forming the oxidized material 114. The oxidized material 114 (e.g., the oxidized first conductive material) may be produced by subjecting a first surface (e.g., an exposed surface) of the first conductive material 112 to the plasma oxidation act (e.g., an oxygen plasma), such as by exposing the first conductive material 112 to a plasma containing an oxidizing agent. The oxidizing agent may include, but is not limited to, one or more of oxygen (O₂), ozone (O₃), air, nitrous oxide (N₂O), carbon dioxide (CO₂), carbon monoxide (CO), water (H₂O), or hydrogen peroxide (H₂O₂). In some embodiments, the oxidizing agent is O₂ and the oxidation act is conducted using an O₂ plasma, which contains reactive oxygen species. The reactive oxygen species are incorporated into and react with the first conductive material 112 to produce the oxidized material 114.

The plasma oxidation act may be conducted for an amount of time sufficient to form the oxidized material 114 to the desired thickness. The plasma oxidation act may be conducted for from about 1 second to about 60 seconds, such as from about 2 seconds to about 40 seconds, from about 5 seconds to about 30 seconds, or from about 10 seconds to about 25 seconds. In some embodiments, the oxidation act is conducted for from about 10 seconds to about 25 seconds. Other process conditions, such as temperature, pressure, gas flow rates, RF power, etc. of the oxidation act may be selected as appropriate to achieve the desired thickness of the oxidized material 114. For example, the plasma oxidation act may be conducted at an RF power of from about 1000 W to about 1300 W. By way of example only, if the first conductive material 112 is titanium nitride, titanium oxynitride may be formed as the oxidized material 114 at a thickness of about 1.8 nm by oxidizing the titanium nitride at an RF power of 1000 W to 1300 W for about 15 seconds.

The oxidized material 114 may be a homogeneous composition in which the oxygen atoms are substantially uniformly distributed in the first conductive material 112. Alternatively, the oxidized material 114 may be a heterogeneous composition in which the oxygen atoms are not substantially uniformly distributed in the first conductive material 112. The heterogeneous composition of the oxidized material 114 may include a gradient of oxygen atoms across the thickness of the oxidized material 114. In some embodiments, the oxidized material 114 is a stoichiometric material. In other embodiments, the oxidized material 114 is an oxygen-rich material. In yet other embodiments, the oxidized material 114 is an oxygen-poor material

Alternatively, the oxidized material 114 may be formed by a deposition technique, such as by depositing one of the oxide materials described above to the desired thickness.

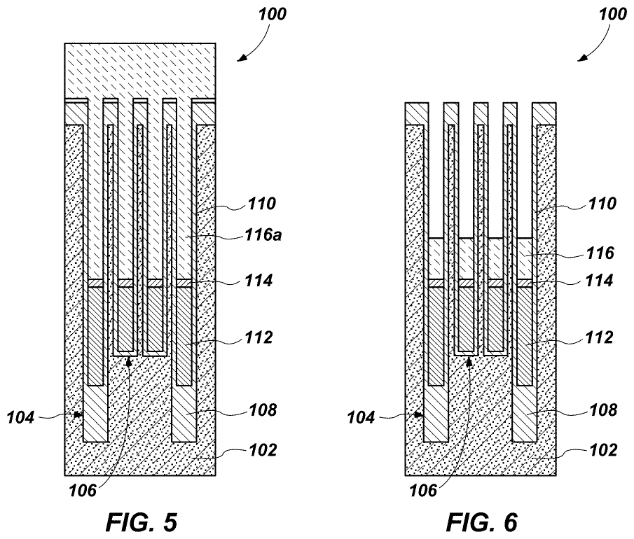

After forming the oxidized material 114, the second conductive material 116a (e.g., an upper conductive material) may be formed in the isolation trenches 104 and the wordline trenches 106 and over the substrate 102, as shown in FIG. 5. As described above, the second conductive material 116a may be a conductive material having a different work function than the first conductive material 112 or having the same work function as the first conductive material 112. The second conductive material 116a may include, but is not limited to, polysilicon. The second conductive material 116a may be formed by conventional techniques. A portion of the second conductive material 116a over the substrate 102 may be removed, as well as a portion of the second conductive material 116a within the isolation trenches 104 and the wordline trenches 106, recessing the second conductive material 116, as shown in FIG. 6. The second conductive material 116a may be removed by conventional techniques. The second conductive material 116 may partially fill the isolation trenches 104 and the wordline trenches 106, with the sidewalls of the gate dielectric material 110 exposed. The oxidized material 114 forms an interfacial material between the first conductive material 112 and the second conductive material 116. A nitride material 118 may be formed in the remaining volume of the isolation trenches 104 and the wordline trenches 106 and over the substrate 102, as shown in FIG. 1.

The wordline structure 100 including the first conductive material 112, the oxidized material 114, and the second conductive material 116 provides improved row hammer characteristics to an electronic device including the wordline structure 100. Without being bound by any theory, it is believed that the oxidized material 114 functions as a so-called “leaky oxide, and improves the “row hammer” characteristic of the memory device, e.g., by lowering the likelihood for the electronic device including the structure 100 to experience undesirable leakage. While the oxidized material 114 as described above may conventionally be considered an insulative material, it was found that the wordline structure 100 according to embodiments of the disclosure provided improved row hammer properties to the electronic device including the wordline structure 100. It was unexpected and surprising that the oxidized material 114 in the wordline structure 100 improved the row hammer properties since other insulative materials, such as silicon oxide or silicon nitride, are not sufficiently leaky to improve row hammer performance. The oxidized material 114 may improve the row hammer (e.g., may reduce the leakage) that may otherwise be exhibited by the wordline structure 100 in use and operation in the electronic device. Therefore, the oxidized material 114 of the wordline structure 100 according to embodiments of the disclosure was determined to improve the row hammer performance properties of the electronic device. It was found, however, that a wordline structure including the oxidized material at a thickness below about 1 nm or at a thickness above about 3 nm provided substantially the same row hammer properties as a conventional wordline structure (e.g., a wordline structure lacking the oxidized material).

Additional process acts may be conducted on the wordline structure 100 to form an electronic device 700 (e.g., an apparatus) that includes the wordline structure 100 and additional components, as shown in FIG. 7. The process acts may be conducted by conventional techniques. The electronic device 700 includes at least one gate 120 (e.g., access line, wordline), a dielectric material 730, at least one bit line 732, and at least one memory cell (not shown). Before forming the dielectric material 730 and the at least one bit line 732, a portion of the another dielectric material 118 may be removed so that a top surface of the another dielectric material 118 and the gate dielectric material 110 are substantially coplanar, forming another dielectric material 118a. Each memory cell is coupled to an associated wordline 120 and an associated bit line 732. The electronic device 700 also includes the active areas 724, which may be aligned at an angle (e.g., at about a forty-five degree angle) relative to the alignment of the wordlines (within the wordline trenches 106) and the bit lines 732 (within the isolation trenches 104). Each wordline (e.g., gate 120) is isolated from the source 726 and drains 728 of the array 800 by the gate dielectric material 110. In some embodiments, the electronic device 700 is a dynamic random access memory (DRAM) device.

The electronic device 700 may include an array 800 (e.g., memory array) that includes the wordline structure 100 as shown in FIG. 8, where the view of FIG. 8 is taken along section line A-A of FIG. 7. The wordlines (e.g., gates 120) may be oriented perpendicular or substantially perpendicular to the bit lines 732. The bit lines 732 may be formed of at least one conductive material. While the bit line 732 is illustrated as a single material in FIG. 7, the bit line 732 may be formed of multiple conductive materials. By way of example only, the bit line 732 may include a metal material over a polysilicon material. The bit line 732 may extend vertically to the source 726, providing electrical communication with the source 726. A digit line contact (not shown) including conductive material 734 extends vertically to the bit line 732 to enable electrical communication with more distal components of the electronic device 700 that includes the wordline structure 100. Contacts formed from the conductive material 734 are in electrical communication with the drains 728.

Accordingly, an apparatus comprising a memory array comprising wordlines, bit lines, and memory cells is disclosed. Each memory cell is coupled to an associated one of the wordlines and an associated one of the bit lines. Each of the wordlines is buried in a substrate and comprises a lower conductive material, an upper conductive material, and an oxidation material of the lower conductive material between the lower conductive material and the upper conductive material.

Accordingly, another apparatus comprising access lines, digit lines, and memory cells is disclosed. The access lines comprise an oxidized material between a first conductive material and a second conductive material, the oxidized material comprising an oxide of the first conductive material.

Accordingly, a method of forming an apparatus is also disclosed. The method comprises forming a first conductive material in trenches of a base material and oxidizing a portion of the first conductive material to form an oxidized material in the trenches. A second conductive material is formed in the trenches and a portion of the second conductive material is removed to recess the second conductive material in the trenches.

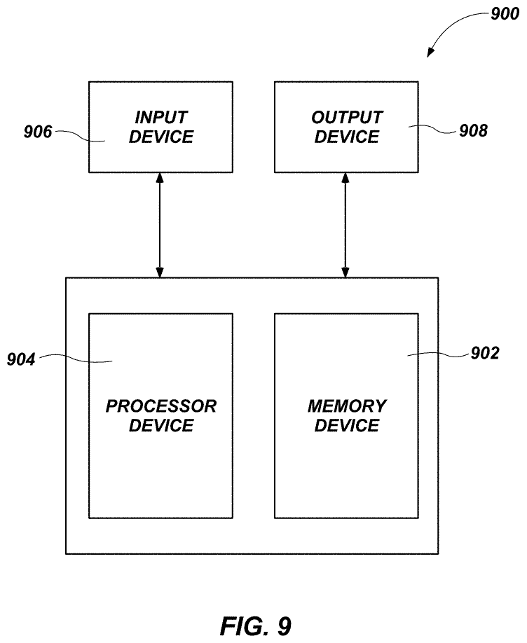

An electronic system 900 is also disclosed, as shown in FIG. 9, and includes electronic devices 700 and wordline structures 100 according to embodiments of the disclosure. FIG. 9 is a simplified block diagram of the electronic system 900 implemented according to one or more embodiments described herein. The electronic system 900 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPad® or SURFACE® tablet, an electronic book, a navigation device, etc. The electronic system 900 includes at least one electronic device 902 (e.g., at least one memory device), which includes memory cells including one or more wordline structures 100 as previously described. The electronic system 900 may further include at least one processor device 904 (often referred to as a “processor”). The processor device 904 may, optionally, include one or more wordline structures 100 as previously described. The electronic system 900 may further include one or more input devices 906 for inputting information into the electronic system 900 by a user, such as, for example, a mouse or other pointing device, a keyboard, a touchpad, a button, or a control panel. The electronic system 900 may further include one or more output devices 908 for outputting information (e.g., visual or audio output) to a user such as, for example, a monitor, a display, a printer, an audio output jack, a speaker, etc. In some embodiments, the input device 906 and the output device 908 may comprise a single touchscreen device that can be used both to input information to the electronic system 900 and to output visual information to a user. The one or more input devices 906 and output devices 908 may communicate electrically with at least one of the memory device 902 and the processor device 904.

Accordingly, an electronic system comprising a processor device operably coupled to an input device and an output device and an electronic device operably coupled to the processor device is disclosed. The electronic device comprises access lines, digit lines, and memory cells, with each memory cell coupled to an associated one of the access lines and an associated one of the digit lines. Each of the access lines comprises a first conductive material, an oxidized material over the first conductive material, and a second conductive material over the oxidized material, with the oxidized material comprising an oxide of the first conductive material.

The following example serves to explain embodiments of the disclosure in more detail. These examples are not to be construed as being exhaustive or exclusive as to the scope of this disclosure.

### Example 1

Wordline structures similar to those shown in FIG. 1 were prepared as described above for FIGS. 1-6. Samples of the wordline structures included titanium nitride deposited in the wordline trenches. After recessing the titanium nitride by etching, the upper surface of the titanium nitride was oxidized by exposing the recessed titanium nitride to an oxygen (O₂) plasma at a flowrate of 350 sccm for 15 seconds and at a pressure of 50 mT. The titanium nitride was oxidized to a 1.8 nm (18 Å) thick titanium oxynitride. After forming the titanium oxynitride, polysilicon was formed over the titanium oxynitride, producing the wordline structures having titanium nitride/titanium oxynitride/polysilicon.

For comparison, a control sample was prepared as described above except that the polysilicon was deposited after etching the titanium nitride, i.e., without exposing the titanium nitride to the 02 plasma. In the control sample, the polysilicon was formed directly on the titanium nitride and no oxidized material was present between the titanium nitride and the polysilicon.

As shown in the transmission electron microscopy (TEM) micrographs of FIGS. 10A and 10B, titanium oxynitride (e.g., the oxidized material 114) was produced following exposure to the 02 plasma. The titanium oxynitride was between the titanium nitride (e.g., the first conductive material 112) and the polysilicon (e.g., second conductive material 116). In comparison, no titanium oxynitride was present when the polysilicon was directly deposited after etching the titanium nitride, as shown in FIGS. 11A and 11B.

Elemental analysis (Electron Energy Loss Spectroscopy, EELS) was also conducted on the samples by conventional techniques. For the samples exposed to the O₂ plasma, silicon atoms, oxygen atoms, nitrogen atoms, and titanium atoms were present, as shown in FIG. 10C. The titanium oxynitride (e.g., the oxidized material 114) is identified in FIG. 10C. For the control sample (not exposed to the O₂ plasma), no titanium oxynitride was present, as shown in FIG. 11C.

The row hammer properties of the samples were determined by conventional techniques. As shown in FIG. 12, the row hammer performance of the samples exposed to the O₂ plasma exhibited improved row hammer without decreasing the refresh (edE) properties. FIG. 12 shows the number of fail bits caused by a row hammer test as a function of the number of fail bits caused by a refresh test. In the row hammer test, an aggressor wordline is repeatedly activated and deactivated 5000 times. The fail bits caused by the row hammer test are coupled to victim wordlines that are adjacent to the aggressor wordlines. The refresh test included operations performed at a cycle of 80 msec. Samples including wordline structures similar to those shown in FIGS. 1 and 7 were exposed to an O₂ plasma for 15 seconds at an RF power of 1000 W (sample 3E), to an O₂ plasma for 7 seconds at an RF power of 1300 W (sample 4E), to an O₂ plasma for 7 seconds at an RF power of 700 W (sample 5E), or to an O₂ plasma for 15 seconds at an RF power of 1300 W (sample 6E). A control sample (sample 1C) included no titanium oxynitride, while titanium oxynitride was present with the remaining samples (samples 3E, 4E, 5E, 6E). The samples 3E, 4E, 5E, 6E including the titanium oxynitride exhibited lower row hammer performance without substantially affecting the refresh rate compared to the control wordline structure (sample 1C), as shown in FIG. 12.

While certain illustrative embodiments have been described in connection with the figures, those of ordinary skill in the art will recognize and appreciate that embodiments encompassed by the disclosure are not limited to those embodiments explicitly shown and described herein. Rather, many additions, deletions, and modifications to the embodiments described herein may be made without departing from the scope of embodiments encompassed by the disclosure, such as those hereinafter claimed, including legal equivalents. In addition, features from one disclosed embodiment may be combined with features of another disclosed embodiment while still being encompassed within the scope of the disclosure.

What is claimed is:

1. An apparatus comprising:
a memory array comprising wordlines, bit lines, and memory cells, each memory cell coupled to an associated one of the wordlines and an associated one of the bit lines, each of the wordlines buried in a substrate and comprising:
a lower conductive material;
an upper conductive material; and
an oxidation material of the lower conductive material between the lower conductive material and the upper conductive material.

2. The apparatus of claim 1, wherein the lower conductive material and the upper conductive material are different in work function from each other.

3. The apparatus of claim 1, wherein the lower conductive material and the upper conductive material are the same in work function as each other.

4. The apparatus of claim 1, wherein the lower conductive material comprises titanium nitride, tungsten, or ruthenium and the upper conductive material comprises titanium nitride, tungsten, ruthenium, or polysilicon.

5. The apparatus of claim 1, wherein the oxidation material comprises a thickness of from about 1 nm to about 3 nm.

6. An apparatus, comprising:
access lines, digit lines, and memory cells, the access lines comprising:
an oxidized material between a first conductive material and a second conductive material, the oxidized material comprising an oxide of the first conductive material.

7. The apparatus of claim 6, wherein the oxidized material forms an interface between the first conductive material and the second conductive material.

8. The apparatus of claim 6, wherein the first conductive material comprises titanium nitride, the oxidized material comprises titanium oxynitride, and the second conductive material comprises polysilicon.

9. The apparatus of claim 8, wherein the titanium oxynitride comprises stoichiometric titanium oxynitride.

10. A method of forming an apparatus, comprising:
forming a first conductive material in trenches of a base material;
oxidizing a portion of the first conductive material to form an oxidized material in the trenches;
forming a second conductive material in the trenches; and
removing a portion of the second conductive material to recess the second conductive material in the trenches.

11. The method of claim 10, wherein forming a first conductive material in trenches of a base material comprises forming the first conductive material in isolation trenches and access line trenches in a silicon material.

12. The method of claim 10, wherein oxidizing a portion of the first conductive material to form an oxidized material comprises converting a portion of the first conductive material to the oxidized material.

13. The method of claim 10, wherein oxidizing a portion of the first conductive material to form an oxidized material comprises exposing the first conductive material to an oxygen plasma.

14. The method of claim 10, wherein oxidizing a portion of the first conductive material to form an oxidized material comprises oxidizing the first conductive material comprising titanium nitride, tungsten, or ruthenium to titanium oxynitride, tungsten oxide, or ruthenium oxide.

15. The method of claim 10, wherein oxidizing a portion of the first conductive material to form an oxidized material comprises forming the oxidized material to a thickness of from about 1 nm to about 3 nm.

16. The method of claim 10, wherein forming a second conductive material in the trenches comprises forming the second conductive material over the oxidized material.

17. The method of claim 10, wherein removing a portion of the second conductive material comprises forming a wordline structure comprising the first conductive material, the oxidized material, and a recessed second conductive material in the trenches.

18. The method of claim 17, wherein forming a wordline structure comprises forming the wordline structure within the base material.

19. The method of claim 10, wherein forming a wordline structure comprises partially filling the trenches with the first conductive material, the oxidized material, and the recessed second conductive material.

20. An electronic system, comprising:
a processor device operably coupled to an input device and an output device; and
an electronic device operably coupled to the processor device, the electronic device comprising:
access lines, digit lines, and memory cells, each memory cell coupled to an associated one of the access lines and an associated one of the digit lines, each of the access lines comprising:
a first conductive material, an oxidized material over the first conductive material, and a second conductive material over the oxidized material, the oxidized material comprising an oxide of the first conductive material.
